(19) United States
(12) Patent Application Publication
(10) Pub. No.: US 2003/0201504 A1
(43) Pub. Date: Oct. 30, 2003

(54) Method and apparatus for making nitrided gate oxide

(75) Inventors: Kader Ibrahim, Sungai Petani (MY); Umasangar V. Pillai, Kuala Lumpur (MY)

Correspondence Address: Townsend and Townsend and Crew LLP, 8th Floor, Two Embarcadero Center, San Francisco, CA, 94111, US

(73) Assignee: Silterra, Kulim (MY)

(21) Appl. No.: 10/133,974

(22) Filed: Apr. 24, 2002

(51) Int. Cl. H01L 21/8238; H01L 29/76; H01L 31/062

(52) U.S. Cl. 257/410; 438/216; 257/411; 438/261; 257/412; 257/405

(57) ABSTRACT

A method for forming a semiconductor device having a nitrided gate oxide includes flowing a gas including N₂O into an external torch. The gas is decomposed in the external torch to provide NO. The decomposed gas having NO is flowed into a process chamber including a substrate to form a nitrided gate oxide over the substrate.

### BACKGROUND OF THE INVENTION

The present invention relates to semiconductor device fabrication, more particularly, fabrication of devices having nitrided gate oxide.

Until recently, semiconductor devices, such as N and P type metal oxide semiconductor field effect transistors (MOSFETs) which include polysilicon gates overlying gate oxides, were formed generally with gates composed of pure silicon oxide material. Recently, the trend has been to migrate to the devices with deep submicron gates that require gate oxides of 50 angstrom or less in thickness. To accomplish this scaling down, polysilicon gates of P type have been proposed instead of the traditional polysilicon gates of N type for P-channel MOSFETs to convert the buried channel operation to a surface channel operation. Boron is typically used as dopants for the polysilicon gate of P type.

Boron diffusion from the polysilicon gate to the underlying silicon substrate via a gate oxide provided therebetween degrades the device performance for these P-channel MOSFETs. The thinner the gate oxide, the less effective it is in effectively preventing the boron diffusion. Accordingly, it has been found that a gate oxide having 50 angstroms or less generally cannot effectively prevent the boron diffusion.

One proposed solution is to add a concentration of nitrogen into the gate oxide to more effectively prevent the boron diffusion. Such a gate oxide, i.e., nitrided gate oxide, for a given thickness, has proven to be more effective in reducing boron diffusion than the pure gate oxide. It has been shown that higher nitrogen concentration in the gate oxide improves the effectiveness of boron diffusion prevention.

Many different methods have been proposed for making the nitrided gate oxide. Current commonly used methods involve use of N₂O or NO. One advantage of using N₂O is its lower material cost. However, it requires a higher thermal budget than NO to obtain the same level of nitrogen concentration, which is undesirable for certain deep submicron device fabrication processes.

### BRIEF SUMMARY OF THE INVENTION

In one embodiment, a method for forming a semiconductor device having a nitrided gate oxide includes flowing a gas including N₂O into an external torch. The gas is decomposed in the external torch to provide NO. The decomposed gas having NO is flowed into a process chamber including a substrate to form a nitrided gate oxide over the substrate.

In another embodiment, a method for forming a semiconductor device having a nitrided gate oxide includes flowing an N₂O gas into an external torch set at a temperature of at least about 850° C. The N₂O gas is decomposed in the external torch to provide a decomposed gas including N₂O, NO, and O₂, the NO being of sufficient amount to perform a nitrogen incorporation step within a furnace. The decomposed gas is flowed into the furnace including a substrate to form a nitrided gate oxide having a nitrogen concentration of at least about 1% atomic weight and a thickness of about 50 angstroms or less.

In yet another embodiment, a method for forming a semiconductor device P type metal oxide semiconductor field effect transistor (PMOSFET) on a silicon substrate includes forming an oxide layer a thickness of less than 50 angstroms over the substrate. An N₂O gas is flowed into an external torch set at a temperature of at between about 850° C. and about 1000° C. to decompose the N₂O gas in the external torch to provide a decomposed gas including N₂O, NO, and O₂. The decomposed gas including N₂O, NO, and O₂ is flowed into a furnace wherein the substrate with the oxide layer is provided. The substrate is annealed within the furnace in an environment of the decomposed gas to incorporate nitrogen from N₂O and NO into the gate oxide layer overlying the substrate to form a nitrided gate oxide having a nitrogen concentration of at least about 1% atomic weight and a thickness of more than about 50 angstroms. A temperature within the furnace is maintained at between 700° C.-800° C. during the anneal step. A polysilicon layer overlying the nitrided gate oxide is formed. The polysilicon layer has a concentration of boron. The nitrogen concentration in the nitrided gate oxide reduces diffusion of boron from the polysilicon layer into the substrate.

### BRIEF DESCRIPTION OF THE DRAWINGS

FIG. 1A illustrates a semiconductor device having a nitrided gate oxide according to one embodiment of the present invention.

FIGS. 1B-1E illustrates a method of fabricating the semiconductor of FIG. 1A according to one embodiment of the present invention.

FIG. 2 illustrates a process system for forming a semiconductor device having a nitrided gate oxide according to one embodiment of the present invention.

FIG. 3A illustrates a schematic cross-sectional view of an external torch used in the process system of FIG. 1 according to one embodiment of the present invention.

FIG. 3B illustrates a schematic cross-sectional view of an external torch used in the process system of FIG. 1 according to another embodiment of the present invention.

FIG. 3C illustrates a schematic cross-sectional view of an external torch used in the process system of FIG. 1 according to yet another embodiment of the present invention.

### DETAILED DESCRIPTION OF THE INVENTION

Embodiments of the present invention relates to fabrication of a semiconductor device having a nitrided gate oxide using N₂O.

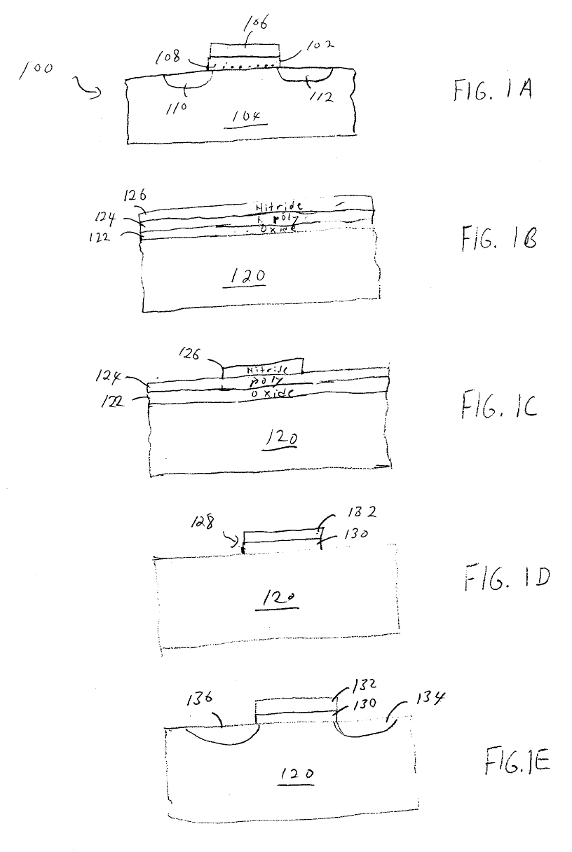

FIG. 1A illustrates a MOSFET 100 having a nitrided gate oxide 102 according to one embodiment of the present invention. The MOSFET 100 is formed on a silicon substrate 104 whereon a semiconductor device is formed. A polysilicon gate of P type 106, doped with boron, is formed overlying the gate oxide. The oxide 102 has a concentration of nitrogen provided therein to reduce diffusion of boron atoms from the gate 106 to the silicon substrate 104 that would degrade the device performance. Diffusion regions 110 and 112 are formed on the substrate, separated by the gate oxide, to form source and drain regions.

FIGS. 1B-1E illustrates a method of forming a semiconductor device having a transistor such as the MOSFET 100 of FIG. 1A according to one embodiment of the present invention. Referring to FIG. 1B, a single crystal silicon substrate 120 having <100> crystalline orientation is provided. An oxide layer 122, having a thickness of 20-50 angstrom, is formed over the substrate by thermal oxidation of the substrate in an oxygen environment. A polysilicon layer 124 is formed over the oxide layer 122 using a chemical vapor deposition (CVD) or low-pressure chemical vapor deposition (LPCVD) process. A nitride layer 126 is formed over the polysilicon layer 124 using CVD or LPCVD. In some applications, a pad oxide is formed prior to forming the gate oxide layer, as is well known by a person skilled in the art. This and related steps have been omitted since they are irrelevant to the understanding of the present embodiment of the invention.

The nitride layer 126 is patterned using a known technique (FIG. 1C). The patterned nitride layer is used as a mask to define a gate structure 128 having a gate poly 130 and a gate oxide 132. Thereafter, the gate poly is used as a mask to form diffusion regions 134 and 136, the formation of which generally involves implantation and diffusion steps, to define the source and drain regions. Although the gate poly 130 and the gate oxide 132 are formed using the same patterned nitride layer in the present embodiment, the gate oxide may be patterned first before a polysilicon layer, such as the poly silicon 124, is formed in other embodiments.

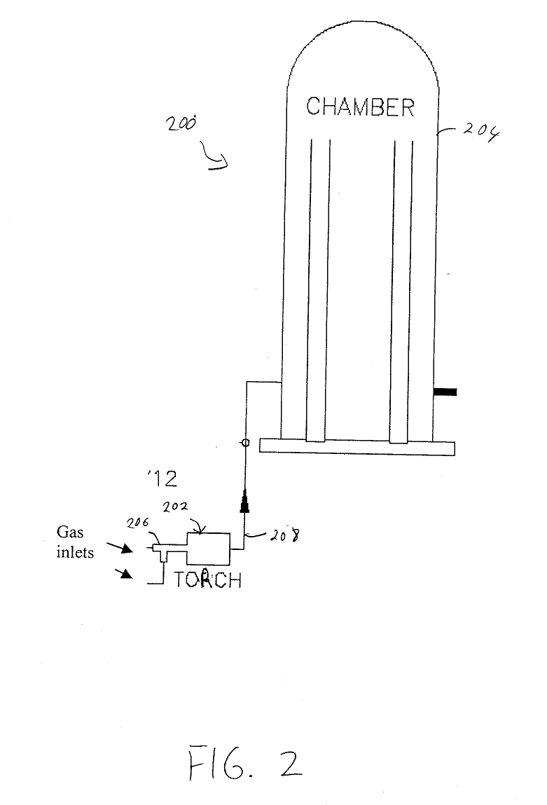

FIG. 2 illustrates a process system 200 for forming a nitrided gate oxide, such as the gate oxide 102 of FIG. 1A, to reduce boron diffusion into the silicon substrate from a gate poly, such as the gate poly 106, according to an embodiment of the present invention. The process system includes an external torch or heater 202 and a process chamber 204 to enable use of relatively cheaper N₂O, rather than NO, to form the nitrided gate oxide, thereby reducing manufacturing cost among other advantages.

Generally, the methods for forming nitrided gate oxides using N₂O involves a relatively high temperature of 850° C. or greater to ensure effective decomposition of N₂O (relatively stable state) to NO (relatively less stable state). Unless the N₂O is effectively decomposed during the gate nitridation step, the resulting nitrided gate oxide is provided with a low concentration of nitrogen that may not be suitable for effectively reducing boron diffusion. Preferably, for effective boron diffusion reduction, about 1% atomic weight of nitrogen is required for a gate oxide having thickness of 40-50 angstrom. Thinner gate oxides generally require higher nitrogen concentration to effectively reduce boron diffusion, accordingly higher process temperature. However, high temperature, e.g., 850° C. to 1150° C., is incompatible with some deep submicron device fabrication techniques. For example, at 850° C. or greater, it becomes difficult to finely control the gate oxide thickness, so that the gate oxide obtained may be significant thicker than the desired thickness.

Referring back to FIG. 2, the process system 200 with the external torch 202 enables the N₂O gas to be heated at high temperature external to the process chamber 204, so that the N₂O gas is sufficiently decomposed prior to being flowed into the process chamber 204. Accordingly, the process chamber 204 may be operated at a lower temperature, e.g., less than 850° C., and a thin nitrided gate oxide, e.g., less than 50 angstrom, may be formed therein.

The torch 202 includes an inlet 206 to receive the N₂O gas, so that the gas may be decomposed within the torch, and an outlet 208 to output the decomposed gas to the process chamber. In one embodiment, the torch 202 is set at 850-900° C., 850-1000° C., or 850-1100° C. The gas flow rate is 1 to 6 liters/min, 1 to 4 liters/min, 1 to 2 liters/min, or 0.5 to 2 liters/min. In one embodiment, the gas consists essentially of N₂O. Alternatively, the gas includes a gas other than N₂O. The flow of N₂O gas, the temperature of the torch 202, and the duration of gas residency within the torch 202 are adjusted to obtain sufficient NO decomposition or cracking for a particular application. For example, if a higher nitrogen concentration within the gate oxide is desired the temperature of the torch and the duration of gas residency may be increased. On the other hand, if a lower concentration is desired, the temperature and duration may be decreased.

Increase of the gas flow rate generally increases the nitrogen concentration level since more nitrogen is provided within the process chamber. However, increased flow rate also requires additional energy to obtain the same level of N₂O decomposition within the torch, i.e., increased the duration of gas residency and/or temperature is required.

The following illustrates a decomposition or cracking process performed within the torch 202 according to one embodiment of the present invention:

N₂O→N₂+O

O+O→O₂

O+N₂O→2NO

O+N₂O→N₂+O₂

O+NO→NO₂

NO₂+N₂O→N₂+O₂+NO

As shown above, the decomposed gas provided to the process chamber includes NO, N₂O, and O₂.

According to the experiments of the inventors, the N₂O flow rate of 4 liters/min requires about 1 minute of resident time within the torch set at temperature of about 850° C. to form a gate oxide having thickness of 40-50 angstrom and nitrogen concentration of 1-3% atomic weight. In one embodiment, the flow rate of N₂O preferably is 6 liters/min or less for optimum results since higher flow rate causes cooling effect and slows the N₂O decomposition or cracking within the torch 202, and may even reverse the decomposition process in certain situations. It should be noted that the above process parameters are torch and chamber specific; accordingly, other process parameters are within the scope of the present invention.

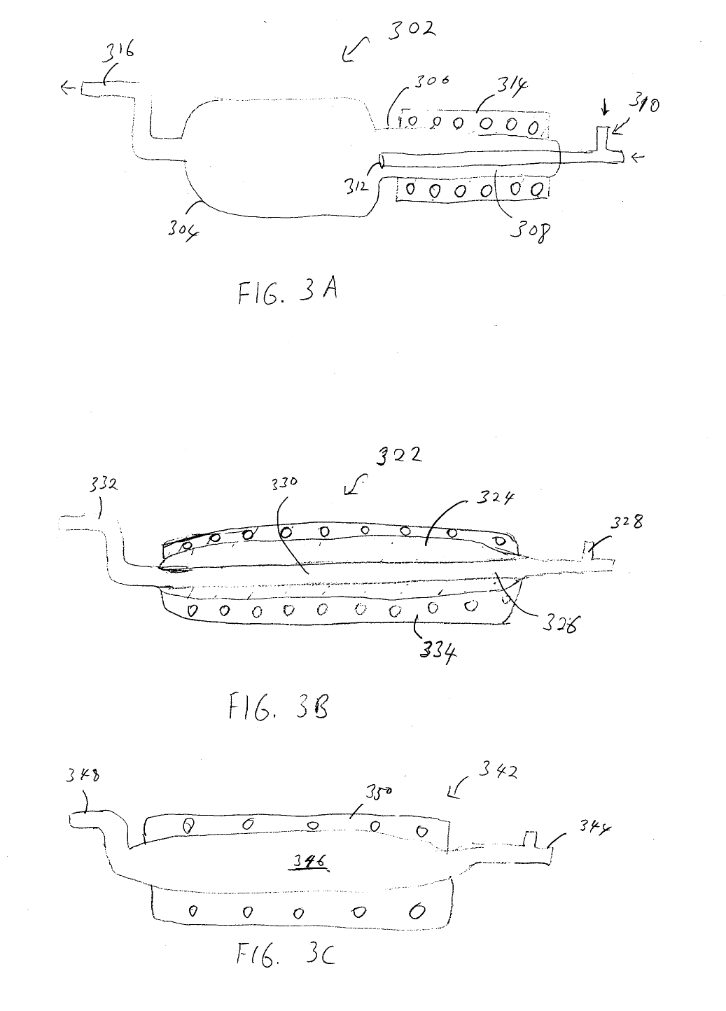

FIG. 3A illustrates a torch or heater 302 that may be used to practice the embodiments of the present invention. The torch 302 includes a body 304, an extension portion 306 coupled to the body at one end. The extension portion receives therein a tube 308 having a tube inlet 310 and a tube outlet 312. N₂O is flowed into the body 304 via the tube inlet 310 and tube outlet 312. A heating mechanism 314 is provided outside the extension portion to heat and decompose the N₂O gas flowing through the tube 308. In one embodiment, the heating mechanism uses heating coils to heat the N₂O gas. The decomposed gas is provided to the process chamber 204 via a torch outlet 316.

FIG. 3B illustrates another torch or heater 322 that may be used to practice the embodiments of the present invention. The torch 322 includes a body 324 to receive therein a tube 326. The tube 326 has a tube inlet 328, a tube body 330, and a tube outlet 332. A heating mechanism 334 is provided outside the body 324 to heat the N₂O gas as it flow through the tube body 330.

FIG. 3C illustrates yet another a torch or heater 342, i.e., a gas decomposing device, that may be used to practice the embodiments of the present invention. The torch 342 includes an inlet 344, a body 346, an outlet 348, and a heating mechanism 350 provided outside the body 346 to heat the N₂O gas as it flow through the body. The N₂O gas that has been sufficiently decomposed is provided to the process chamber.

As shown above in the N₂O decomposition process, the decomposed gas includes N₂O, NO, and O₂. The process chamber 204 (FIG. 2), e.g., a vertical furnace, includes one or more silicon substrate having an oxide layer formed thereon. The chamber is set a temperature of no more than about 850° C., preferably 700-800° C., according to one embodiment of the invention. The substrate is annealed for a given time, e.g., 5-90 minutes. As a result, nitrogen from the gases is incorporated into the oxide layer to provide a desired nitrogen concentration. In one embodiment, a desired nitrogen concentration is 1-3% atomic weight or less 4% atomic weight. It is currently believed that the nitrogen concentration of more than 4% atomic weight may affect the threshold voltage and degrade the device performance for certain applications. During this nitrogen incorporation step, the oxide layer may increase due to the presence of oxygen in the chamber.

In one embodiment, the nitrogen incorporation step is performed after the oxide layer 122 has been formed and prior to the formation of the polysilicon layer 124 (FIG. 1B). In another embodiment, the nitrogen incorporation step may be performed in other stages of the semiconductor device fabrication as warranted by a specific sequence of processes being performed. The concept of preheating a gas external to a process chamber, according to one embodiment of the present invention, is not limited for methods for forming nitrided gate oxide using N₂O. One or more of the embodiments of the present invention may be used for other processes requiring gas decomposition at high temperature but do not desire a high thermal budget.

Accordingly, the embodiments described above are provided merely as exemplary embodiments and should not be used to limit the scope of the present invention. The scope of the invention should be interpreted using the appended claims.

What is claimed is:

1. A method for forming a semiconductor device having a nitrided gate oxide, the method comprising:
flowing a gas including N₂O into an external torch;
decomposing the gas in the external torch to provide NO; and
flowing the decomposed gas having NO into a process chamber including a substrate to form a nitrided gate oxide over the substrate.

2. The method of claim 1, wherein a temperature of the external torch is set at greater than 850° C.

3. The method of claim 1, wherein a temperature of the external torch is set between 850-900° C.

4. The method of claim 1, wherein a temperature of the external torch is set between 850-1000° C.

5. The method of claim 1, wherein a temperature of the external torch is set between 850-1150° C.

6. The method of claim 1, wherein the gas flow rate into the external torch is no more than 6 liters/min.

8. The method of claim 1, wherein the flow rate of the gas into the external torch is between 1-6 liters/min.

9. The method of claim 1, wherein the process chamber is a furnace, the nitrided gate oxide is formed by annealing the substrate in an environment of the decomposed gas.

10. The method of claim 9, wherein the gas is N₂O and the decomposed gas includes a sufficient amount of NO to form a nitrided gate oxide having a thickness of no more than 50 angstrom and a nitrogen concentration of at least about 1% atomic weight.

11. The method of claim 1, wherein the process chamber is set at a temperature of no more than 850° C.

12. The method of claim 11, wherein the process chamber is set at a temperature between about 700° C. to about 800° C.

13. The method of claim 11, wherein the substrate has an oxide layer formed thereon prior to the decomposed gas is flowed into the process chamber.

14. The method of claim 1, wherein the formed nitrided gate oxide is no more than 50 angstroms thick and has a nitrogen concentration of at least 1% atomic weight.

15. The method of claim 14, wherein an interior of the process chamber is set at a temperature of about 850° C. or less.

16. A method for forming a semiconductor device having a nitrided gate oxide, the method comprising:
flowing an N₂O gas into an external torch set at a temperature of at least about 850° C.;
decomposing the N₂O gas in the external torch to provide to provide a Hi decomposed gas including N₂O, NO, and O₂, the NO being of sufficient amount to perform a nitrogen incorporation step within a furnace; and
flowing the decomposed gas into the furnace including a substrate to form a nitrided gate oxide having a nitrogen concentration of at least about 1% atomic weight and a thickness of about 50 angstroms or less.

17. The method of claim 16, wherein the substrate includes an oxide layer overlying the substrate prior to the decomposed gas is flowed into the furnace.

18. A method for forming a semiconductor device P type metal oxide semiconductor field effect transistor (PMOSFET) on a silicon substrate, the method comprising:
forming an oxide layer a thickness of less than 50 angstroms over the substrate;
flowing an N₂O gas into an external torch set at a temperature of at between about 850° C. and about 1000° C. to decompose the N₂O gas in the external torch to provide a decomposed gas including N₂O, NO, and O₂;
flowing the decomposed gas including N₂O, NO, and O₂ into a furnace wherein the substrate with the oxide layer is provided;
annealing the substrate within the furnace in an environment of the decomposed gas to incorporate nitrogen from N₂O and NO into the gate oxide layer overlying the substrate to form a nitrided gate oxide having a nitrogen concentration of at least about 1% atomic weight and a thickness of more than about 50 angstroms, a temperature within the furnace being maintained at between 700° C.-800° C. during the anneal step; and
forming a polysilicon layer overlying the nitrided gate oxide, the polysilicon layer having a concentration of boron,
wherein the nitrogen concentration in the nitrided gate oxide reduces diffusion of boron from the polysilicon layer into the substrate.

19. A process system, comprising:
a chamber to receive a semiconductor substrate and form a nitrided gate oxide on the substrate, the chamber including an input port, wherein the chamber is maintained at a first temperature of less than about 850° C.; and
a torch external to the chamber having an input port, an output port, and a heater, the input port being configured to receive a gas including N₂O, the heater configured to heat the gas provided within the torch at a second temperature that is higher than the first temperature to decompose at least a portion of the gas, the output port being coupled to the input port of the chamber to flow the decomposed gas into the chamber.
